(19) United States
(12) Patent Application Publication
(10) Pub. No.: US 2003/0128054 A1
(43) Pub. Date: Jul. 10, 2003

(54) Comparator circuit for comparing two electric voltages

(76) Inventor: Cord-Heinrich Kohsiek, Ellerau (DE)

Correspondence Address: PHILIPS ELECTRONICS NORTH AMERICAN CORP, 580 WHITE PLAINS RD, TARRYTOWN, NY, 10591, US

(21) Appl. No.: 10/316,768

(22) Filed: Dec. 11, 2002

(30) Foreign Application Priority Data
Dec. 14, 2001 (DE) 10161382.2

(51) Int. Cl. H03F 3/45

(52) U.S. Cl. 327/53

(57) ABSTRACT

A comparator circuit for comparing two electric voltages, the comparator circuit comprising a differential amplifier with a current mirror as a load, characterized in that two current branches comprise two differential transistor amplifiers (2, 3) with two current mirrors (4, 5) as a load, in which the bases of the differential amplifiers (2, 3) represent the comparator input, and in that both current mirrors (4, 5) are each constituted by a diode (6, 9) and an associated transistor (7, 8), in which the comparator output value is either one of the currents through the diodes (6, 9) or one of the voltages across the diodes (6, 9) or the difference between the two diode voltages (6, 9).

The invention relates to a comparator circuit for comparing two electric voltages, comprising a differential amplifier with a current mirror as a load.

Such circuits are known (U.S. Pat. No. 4,144,545, DE-PS 31 02 796).

In the known comparator circuits corresponding to an operational amplifier, the desired properties such as amplification, hysteresis and switching threshold are realized by the implementation of the feedback. This means that the switching thresholds of the hysteresis are not adjustable independently of each other and that the circuit comprises a relatively large number of components.

It is an object of the present invention to provide a comparator circuit of the type described in the opening paragraph, consisting of a small number of components, consuming a small quantity of current and providing the possibility of adjusting the switching thresholds of the hysteresis to a wide extent.

This is achieved in that in a comparator circuit of the type described in the opening paragraph two differential transistor amplifiers with two current mirrors as a load are provided in two current branches, in which the bases of the differential amplifier represent the comparator input, and in that both current mirrors are each constituted by a diode and an associated transistor, in which the comparator output value is either one of the currents through the diodes or one of the voltages across the diodes, or the difference between the two diode voltages.

These and other aspects of the invention are apparent from and will be elucidated with reference to the embodiments described hereinafter.

In the drawings:

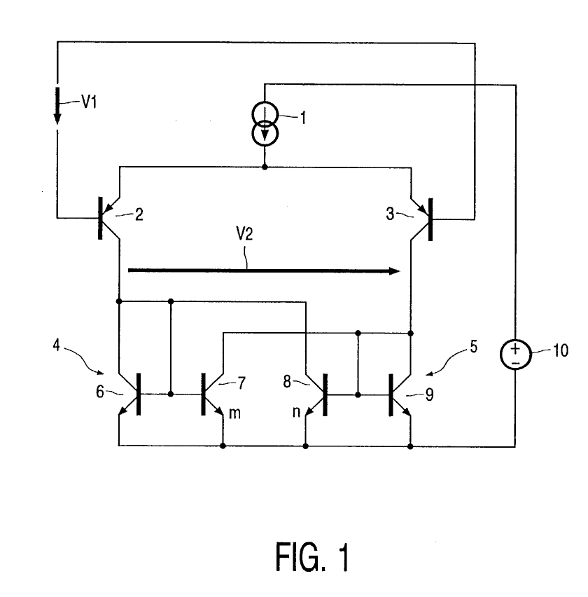

FIG. 1 shows the comparator circuit according to the invention, with a differential amplifier with two current mirrors.

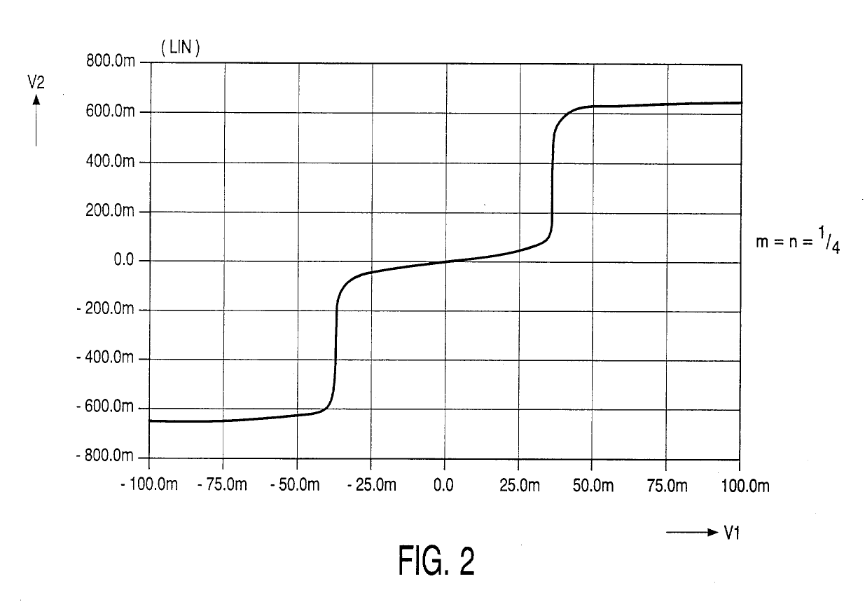

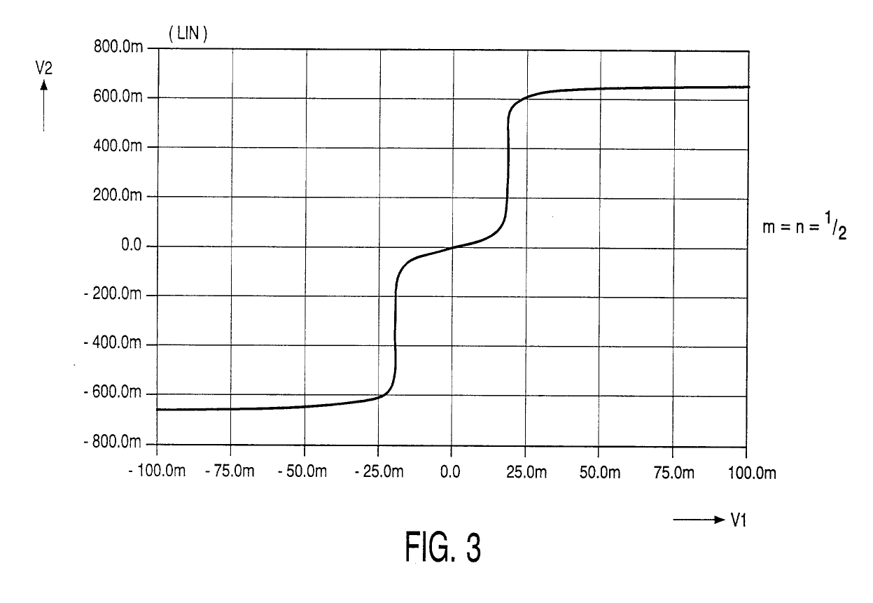

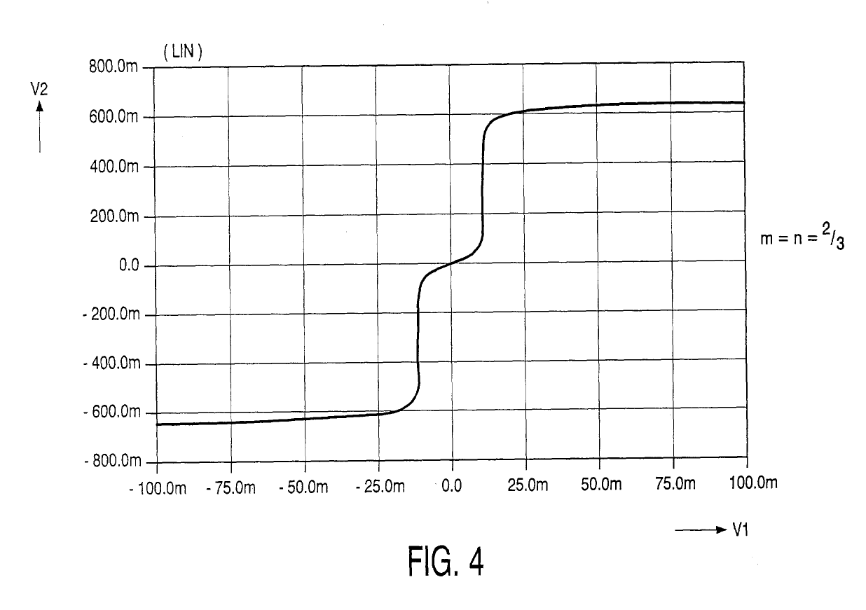

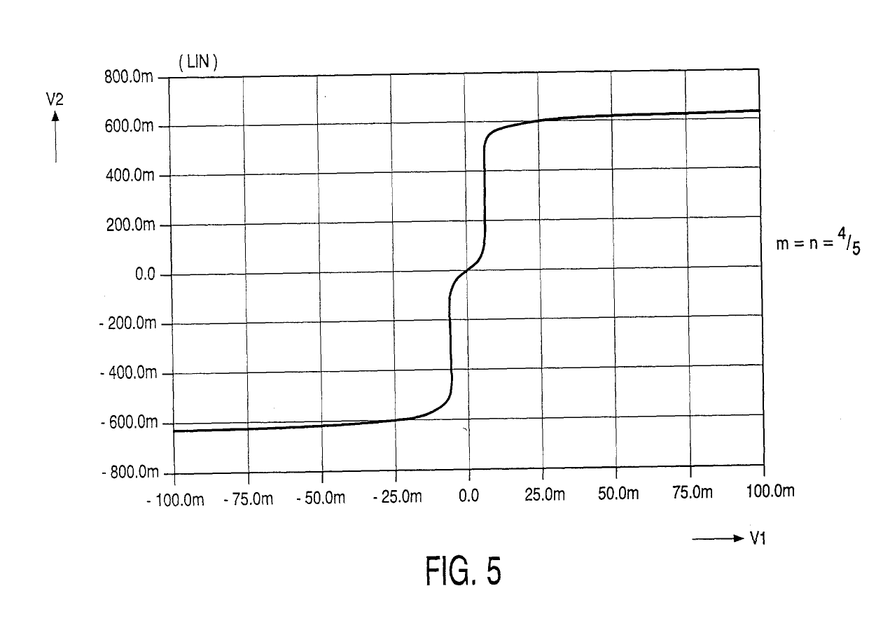

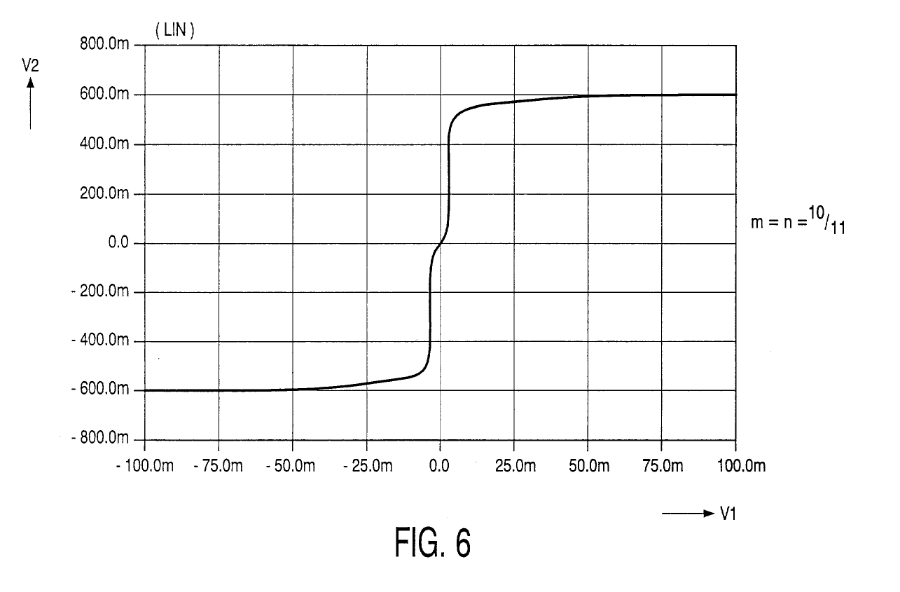

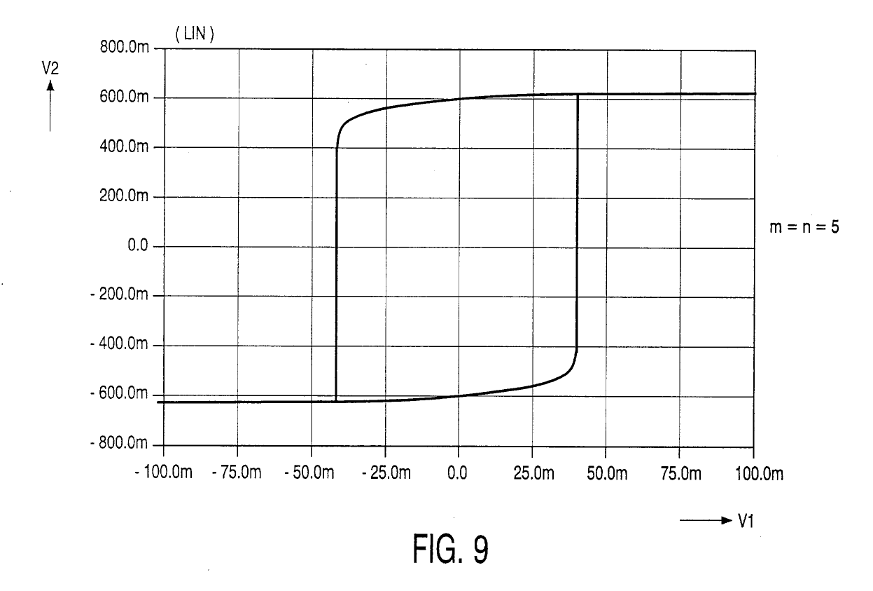

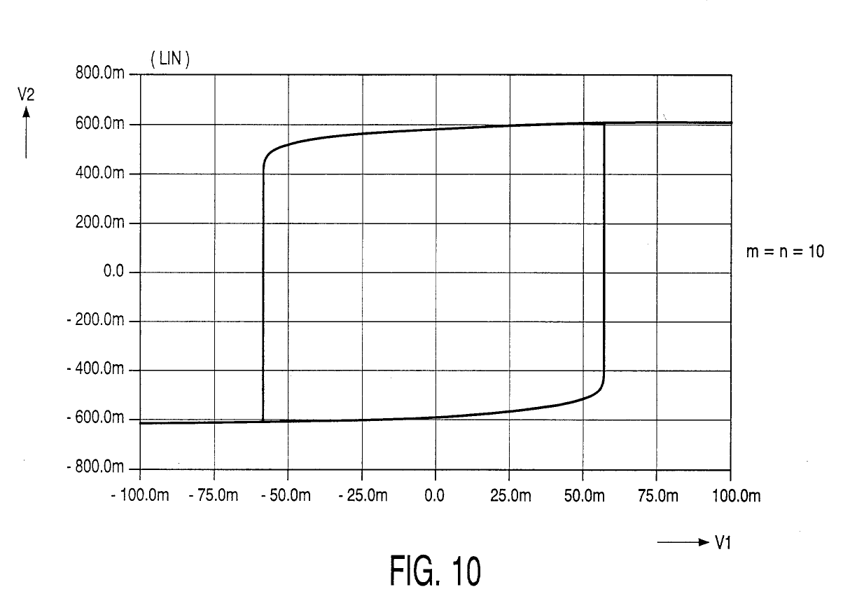

FIGS. 2 to 11 show characteristic curves of the output voltage in dependence upon the input voltage for the comparator circuit according to the invention, in which the amplifications of the two current mirrors assume different values.

In the circuit of FIG. 1, two transistors 2 and 3 configured as differential amplifiers are connected to a current source 1 and via a power supply voltage 10 in the conventional way. The bases of the two differential amplifiers 2 and 3 constitute the input of the comparator circuit which is denoted by V1. This is the differential voltage of two differential voltages to be compared, which are not indicated in the Figure.

Current mirrors 4 and 5 constituted by a pair of transistors 6, 7 and 8, 9, respectively, are connected to the two transistors 2 and 3, respectively, while one of the two transistors (6 or 9) is switched as a diode.

The current mirror 4 comprises the diode 6 and has an amplification m. The current mirror 5 comprises the diode 9 and has an amplification n.

In FIG. 1, the output voltage V2 is the differenctial voltage between the anodes of the diodes 6 and 9, where also the current through the diode 6 or through the diode 9 or the corresponding voltages via the diodes 6 and 9 may be output values. The current mirrors 4 and 5 cause the current change in the diodes 6 and 9, based on the change of the input voltage V1, to be further amplified. This amplification may be adjusted by a suitable choice of the current mirror translations m and n.

FIGS. 2 to 11 show characteristic curves of the output voltage V2 (y axis) with respect to the input voltage V1 (x axis) at differently adjusted current mirror translations.

When the two current mirror translations m and n are between 0 and 1, an amplification between 1 and very high values can be achieved between the output voltage and the input voltage.

In the characteristic curves shown in FIGS. 2 to 6, the two current mirror translations m and n are of equal value but have been chosen to be variable. As a result, symmetrical curves with two thresholds, but without hysteresis are obtained.

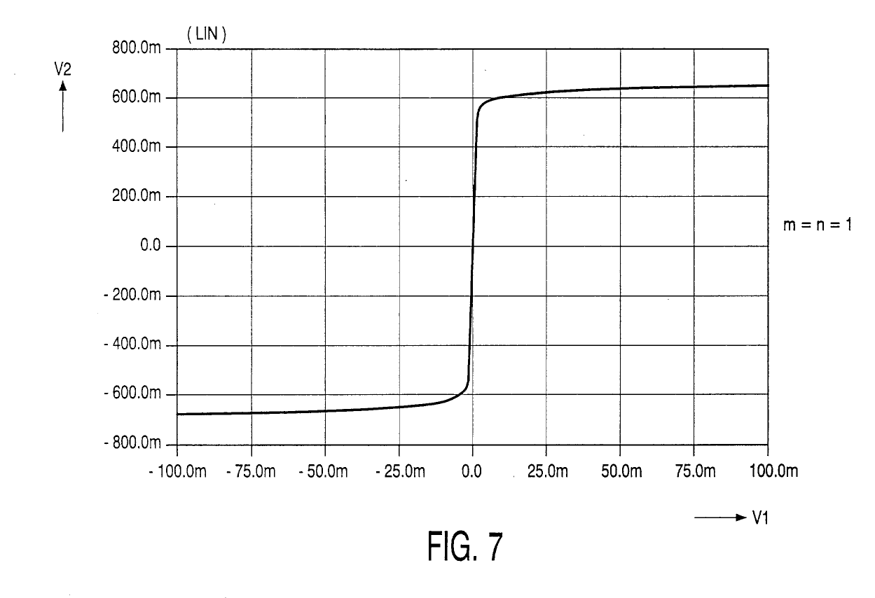

FIG. 7 shows the border case, namely where the two current mirror translations are adjusted at 1, so that an infinitely large amplification is obtained (at least theoretically) at the zero-crossing.

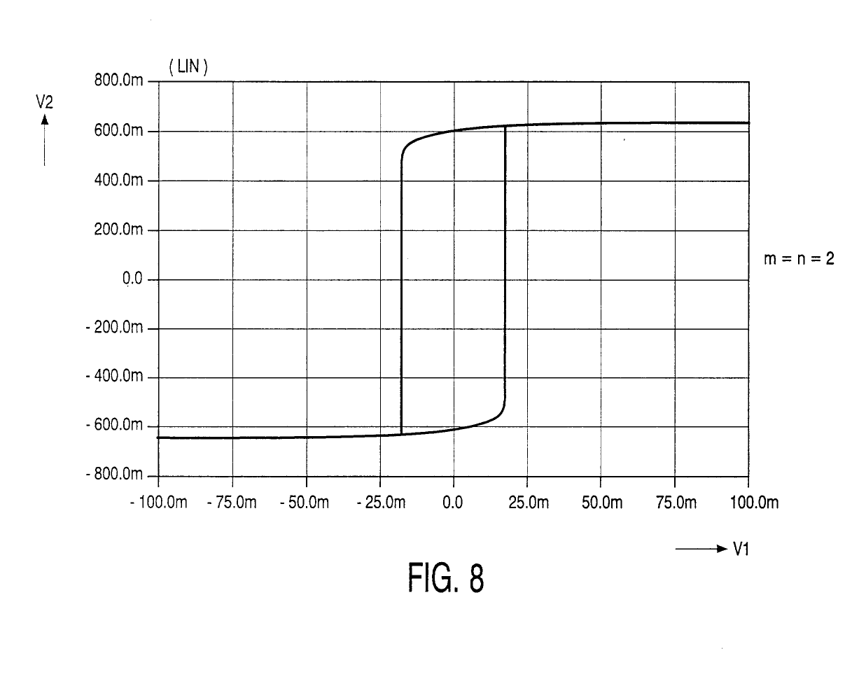

In FIGS. 8 to 10, the current mirror translations m and n are equal but have been adjusted to be larger than 1 so that characteristic curves with hysteresis are obtained.

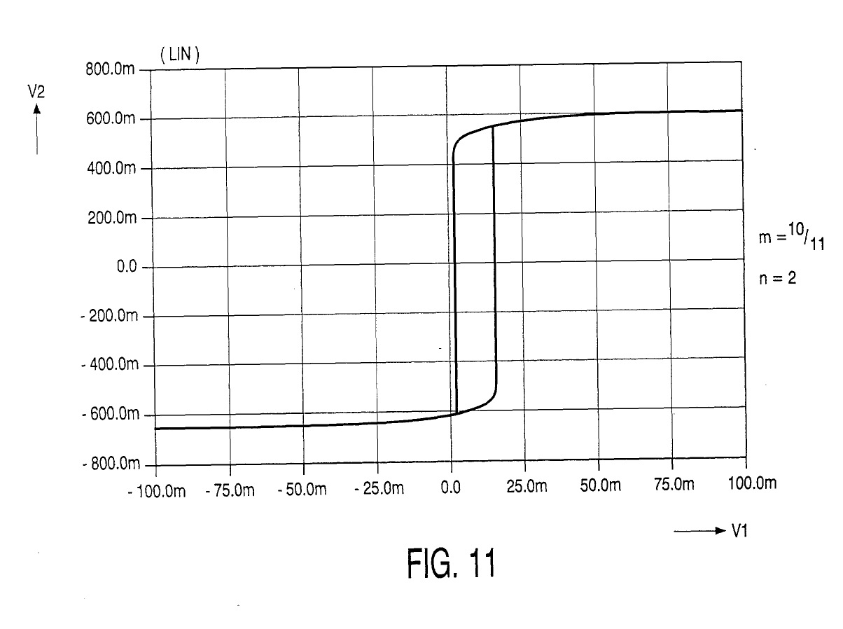

FIG. 11 finally shows the characteristic curve for differently adjusted amplifications of the two current mirrors so that an asymmetrical characteristic curve with hysteresis is obtained.

The comparator circuit according to the invention can be realized with any type of transistor, namely pnp transistors, npn transistors or n channel transistors or p channel transistors or field effect transistors.

The advantage of the comparator circuit according to the invention is particularly that only a small number of components, inter alia no resistors, are required. The hysteresis can be easily realized and the two hysteresis thresholds can be adjusted independently of each other, for example, in such a way that two threshold can be detected. Moreover, the comparator circuit according to the invention has a good temperature stability at a low power consumption.

1. A comparator circuit for comparing two electric voltages, the comparator circuit comprising a differential amplifier with a current mirror as a load, characterized in that two current branches comprise two differential transistor amplifiers (2, 3) with two current mirrors (4, 5) as a load, in which the bases of the differential amplifiers (2, 3) represent the comparator input, and in that both current mirrors (4, 5) are each constituted by a diode (6, 9) and an associated transistor (7, 8), in which the comparator output value is either one of the currents through the diodes (6, 9) or one of the voltages across the diodes (6, 9) or the difference between the two diode voltages (6, 9).
